(19) United States
(12) Patent Application Publication
(10) Pub. No.: US 2004/0038489 A1
(43) Pub. Date: Feb. 26, 2004

(54) Method to improve performance of microelectronic circuits

(76) Inventors: Lawrence A. Clevenger, LaGrangeville, NY (US); George C. Feng, Poughkeepsie, NY (US); James M.E. Harper, Yorktown Heights, NY (US); Louis L. Hsu, Fishkill, NY (US)

Correspondence Address: FREDERICK W. GIBB, III, MCGINN & GIBB, PLLC, 2568-A RIVA ROAD, SUITE 304, ANNAPOLIS, MD, 21401, US

(21) Appl. No.: 10/224,878

(22) Filed: Aug. 21, 2002

(51) Int. Cl. H01L 21/336

(52) U.S. Cl. 438/303

(57) ABSTRACT

A method and structure for an integrated circuit transistor structure includes a gate conductor that has a first conductive material and a second material. The invention has non-deformable spacers adjacent the gate conductor and a gap between the gate conductor and the spacer. The first conductive material can be polysilicon and the second material can be either a metal or a polymer. The second material acts as a placeholder for the gap. In the invention, the gap holds ambient gas and decreases resistance of the gate conductor.

### BACKGROUND OF THE INVENTION

Field of the Invention

The present invention generally relates to integrated circuit wiring and more particularly to wiring structures that utilize air gaps to decrease resistance and capacitance.

### SUMMARY OF THE INVENTION

The invention described below reduces both resistance and capacitance of an interconnect wiring. In an RC reduction scheme implementation of the invention, at the polysilicon wiring level, the resistivity of polysilicon is inherently much higher and the capacitive coupling effective is more significant than at other metal levels. The invention creates an air channel along the sidewalls, and/or on top of the wiring by using such processes as metal diffusion or polymer decomposition. With the invention, a self-aligned contact process is used to create the gate structure, without which a high risk of gate-to-contact shorting would occur. With the invention, the air channel is embedded inside a hard shell so that the integrity of the

In order to attain the object(s) suggested above, there is provided, according to one aspect of the invention, an integrated circuit transistor structure that includes a gate conductor that has a first conductive material and a second material. The invention has a non-deformable spacer adjacent the gate conductor and a gap between the gate conductor and the spacer. The first conductive material can be polysilicon and the second material can be either a metal or a polymer. The second material acts as a placeholder for the gap. In the invention, the gap holds ambient gas that decreases resistance of the gate conductor.

The invention also includes a method of forming a transistor in an integrated circuit structure. The invention first forms a gate conductor. Next, the invention deposits a second material over the gate conductor. The invention then forms non-deformable spacers over the second material and anneals the integrated circuit structure to form a gap between the gate conductor and the non-deformable spacers. Before the invention deposits the second material, a process undercuts the sides of the gate conductor. After the depositing of the second material, a process removes portions of the second material such that the second material remains substantially only within undercut portions of the sides of the gate conductor. The undercutting and removing processes maintain a desired length of the gate conductor. The annealing process drives the second material into the gate conductor. Again the gate conductor can be polysilicon and the second material can be either a metal or a polymer. The gap decreases resistance of the conductor. The conductor can be a gate conductor, a contact, or a wiring line.

### BRIEF DESCRIPTION OF THE DRAWINGS

The foregoing and other objects, aspects and advantages will be better understood from the following detailed description of a preferred embodiment(s) of the invention with reference to the drawings, in which:

FIG. 1 is a cross-sectional schematic diagram of a partially completed integrated circuit structure according to the invention;

FIG. 2 is a cross-sectional schematic diagram of a partially completed integrated circuit structure according to the invention;

FIGS. 3A and 3B are cross-sectional schematic diagrams of partially completed integrated circuit structures according to the invention;

FIG. 4 is a cross-sectional schematic diagram of a partially completed integrated circuit structure according to the invention;

FIG. 5 is a cross-sectional schematic diagram of a partially completed integrated circuit structure according to the invention;

FIGS. 6A and 6B are cross-sectional schematic diagrams of partially completed integrated circuit structures according to the invention;

FIG. 7 is a cross-sectional schematic diagram of a completed integrated circuit structure according to the invention;

FIG. 8 is a top-view schematic diagram of a completed integrated circuit structure according to the invention; and

FIG. 9 is a flow diagram illustrating a preferred method of the invention.

### DETAILED DESCRIPTION OF PREFERRED EMBODIMENTS OF THE INVENTION

The invention forms gaps along conductive lines in integrated circuit structures using a number of different methods. For example, one method relies on metal diffusion into a silicon gate material to create the gaps. A second approach to form channels (gaps) relies on polymer decomposition. In one embodiment, the channels are located on both sides of a gate conductor and are buried underneath spacers. The inventive structure is compatible with borderless contact schemes and provides sufficient physical strength to be used with contact studs.

In order to form the channels, the invention relies upon the principle that the volume of material decreases during most metal-silicide reactions which may be taken up by deformation of the surrounding material or by forming a void. Whether a void (or air gap) forms will depend on the integrity of the interfaces (adhesion) and on the details of the diffusion process, i.e. whether diffusing atoms are replaced by vacancies or by other diffusing atoms in their place. In the present invention, the surrounding material is chosen to not deform during silicide formation, thereby favoring the formation of a void or gap.

More specifically, in the reaction between metals and silicon, the resulting volume of the reacted region is typically smaller than the starting volume of the metal plus silicon. For example, in the reaction of Ti with Si, Si is the dominant diffusing species throughout the sequence of phase formation which ends with the TiSi2 phase forming at about 800o C. The relative thickness of the reacting species are: 1 nm of Ti reacts with 2.27 nm of Si to form 2.51 nm of TiSi2 (see Silicides for VLSI Applications, S. P. Murarka, p. 130, Academic Press 1983, hereinafter “Murarka”). Therefore, the ratio of the volume of the final CoSi2 phase to the volume of the starting Co plus Si is 2.51/3.27, or a ratio of 0.77. Therefore, the volume decreases by 23%.

In another example, the reaction of Co with Si, the dominant diffusing species changes with increasing temperature from Co to Si and back to Co, resulting finally in the CoSi2 phase at about 750° C. The relative thickness for the Co-Si reaction are: 1 nm Co reacts with 3.64 nm Si to form 3.52 nm CoSi2. In this case, the volume decreases by 24%. The corresponding values for other transition metals are found in Murarka.

Experiments performed by the inventors show that the line capacitance and line-to-line coupling capacitance reduce by 30% and 38%, respectively, based on typical 0.11 um ground-rules, if 50% of the thickness for GC sidewall oxide and nitride spacer were replaced by a channel gap. For the limiting case were the entire volume of GC sidewall oxide and nitride spacer were replaced, the reduction in line capacitance and line-to-line capacitance would be 44% and 54% respectively. Therefore, the present inventors have discovered that the bulk of the benefit for using air gap around conductor lines can be realized by only partially replacing the adjoining spacer material with a gap, and that the entire spacer does not have to be replaced.

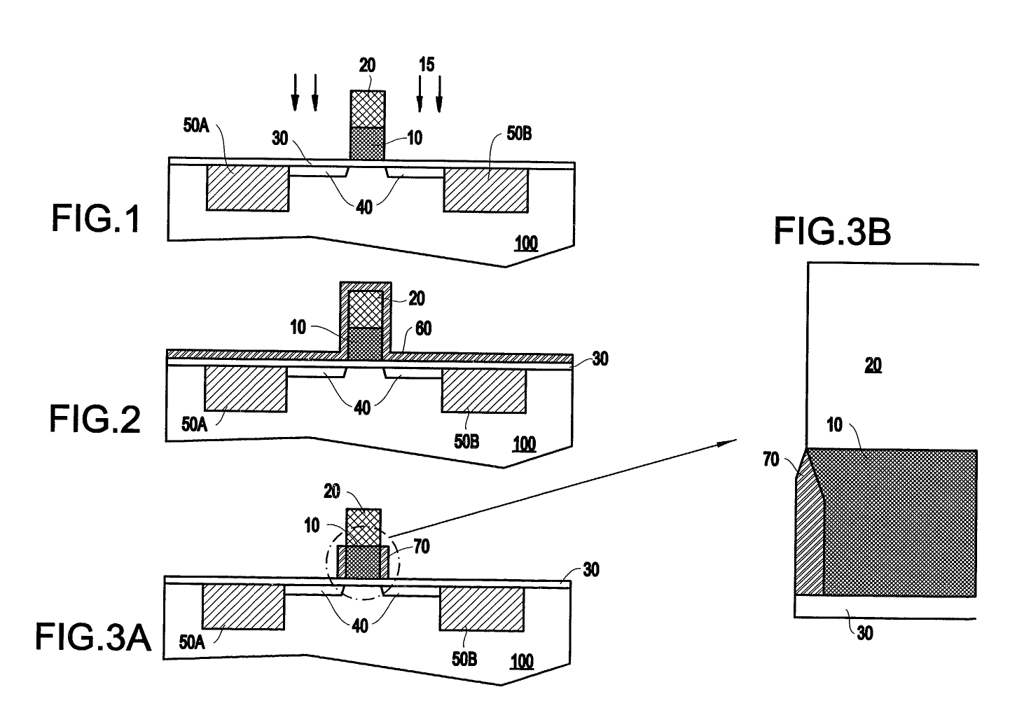

FIG. 1 shows a cross-sectional view of a substrate 100 that includes a gate 10 capped (e.g., with a thick nitride 20), source/drain LDD (lightly doped drain) regions 40, gate dielectric 30, and shallow trench regions 50A and 50B. The following description will illustrate two examples of the invention, from which those ordinarily skilled in the art would understand many equivalent structures and methods. As shown in FIG. 2, thin layer 60 is deposited over the gate stack 10, 20, and gate oxide 30. In one embodiment, this layer 60 comprises a metal such as cobalt or titanium or an alloy of any combination of the above. Since the metal 60 will react with polysilicon 10, it will partially diffuse into the polysilicon 10. Not only does this create a vacuum region along the sidewall of the gate structure, but also the gate conductivity can be significantly increased as the result of metal diffusion into the polysilicon 10. In another embodiment, the layer 60 comprises a self-decomposable polymer, such as Nornornene-type polymer, polyimide, or any combination of the foregoing. This sacrificial layer 60 will later decompose into gaseous products which are removed by diffusion. This creates pockets (gaps) along the gate conductor.

After deposition of the layer 60, an etch-back step is carried out to form a temporary spacer (e.g., placeholder) 70 from material 60 along the gate sidewalls as shown in FIG. 3A. FIG. 3B illustrates this portion of the structure in greater detail. In order to not change the gate length dimension, the invention slightly undercuts the gate as shown in FIG. 3B. This undercutting process removes portions of the material 60 before the material is deposited such that the material 60 remains substantially only within undercut portions of the sides of the gate conductor. The undercutting and removing processes maintain a desired length of the gate conductor. The undercut dimension will then be compensated by metal silcide formation at the sidewalls of the gates during the annealing step, as discussed below and shown in detail in FIG. 6B.

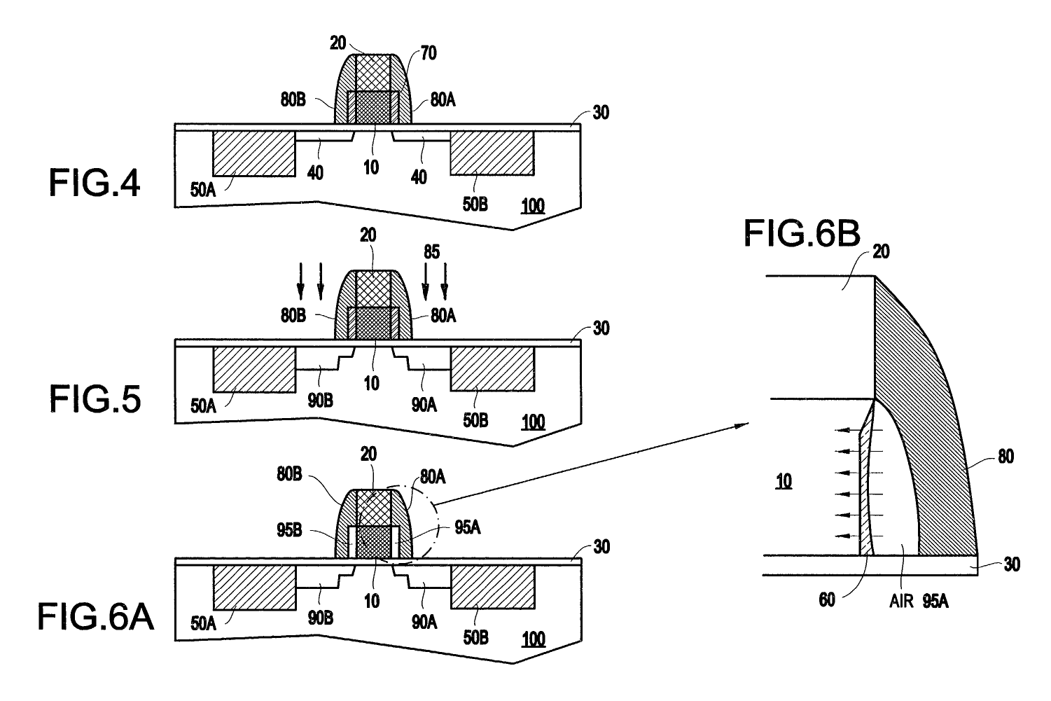

A spacer 80A, 80B (e.g., nitride, silicon dioxide, or silicon oxynitride, etc.) is formed using a conventional spacer processes (as shown in FIG. 4), and a source/drain implant diffusion step (shown in FIG. 5) is carried out to form source/drain junctions. The spacer thickness is controlled considering the undercut, and the temporary spacer dimensions, so that source/drain junction will be positioned properly. For example, a spacer thickness of approximately 10 nm should be sufficient to support borderless contacts as well as stud formation.

An annealing process is carried out to drive the metal 60 into the gate conductor 10 (first embodiment), or to decompose the polymer 60 (second embodiment) so that channels (e.g., air gaps, gaps, pockets, etc.) 95A, 95B are formed along the sidewalls of the gate conductor (FIG. 6). As mentioned previously, the spacers 80A, 80B are substantially rigid (e.g., non-deformable during the annealing process) so that the gap 95A, 95B is properly formed. In other words, the spacers 80A, 80B do not conform (deform) to accommodate the reduction in the size of the material 60. To the contrary, the spacers 80A, 80B remain substantially rigid during the annealing process so that the gap 95A, 95B forms.

The gap will generally comprise ambient gases present during the manufacturing process. For example, if air is present during manufacturing, the gases in the gap will comprise nitrogen, oxygen, hydrogen, etc. Since the volume of the spacer 70 reduces during the annealing process, the material 60 can be considered a placeholder for the gap 95A, 95B. As mentioned above, there is not a need to consume all the metal 60 in order to make a sufficient gap.

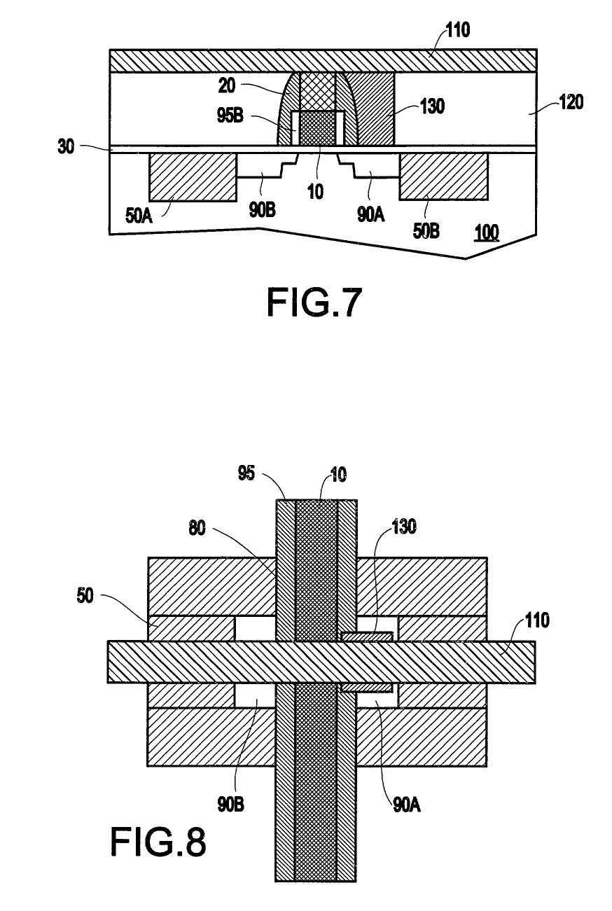

The remaining processes shown in FIGS. 7 and 8 are conventional steps used to provide contact studs 130 and the next wiring level 110. As shown in FIG. 7, due to the existence of the gap 95A, 95B, the first wiring to gate conductor capacitive coupling is drastically reduced. A top view of the inventive high-performance device and interconnect is shown in FIG. 8. Here, the first metal wire 110 contacts the drain junction 90A of the device through a contact stud 130.

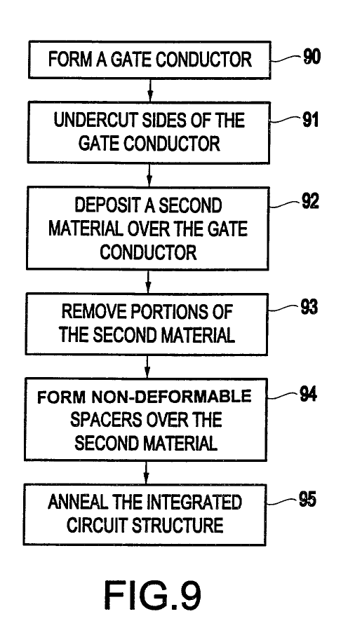

FIG. 9 is a flow diagram of the integrated circuit structure. First, the invention forms a gate conductor 90, then undercuts sides of the gate conductor 91, and deposits a second material over the gate conductor 92. Then the invention removes portions of the second material 93, forms non-deformable spacers over the second material 94, and finally anneals the integrated circuit structure 95.

The invention reduces both resistance and capacitance of an interconnect wiring. In an RC reduction scheme implementation of the invention, at the polysilicon wiring level, the resistivity of polysilicon is inherently much higher and the capacitive coupling effective is more significant than at other metal levels. The invention creates an air channel along the sidewalls, and/or on top of the wiring by using such processes as metal diffusion or polymer decomposition. With the invention, a self-aligned contact process is used to create the gate structure, without which a high risk of gate-to-contact shorting would occur. With the invention, the air channel is embedded inside a hard shell so that the integrity of the interconnect structure is preserved.

While the invention has been described in terms of preferred embodiments, those skilled in the art will recognize that the invention can be practiced with modification within the spirit and scope of the appended claims.

What is claimed is:

1. An integrated circuit wiring structure comprising:
a conductor;
non-deformable spacers adjacent said conductor; and
a gap between said conductor and said spacers.

2. The integrated circuit in claim 1, wherein said conductor comprises a first conductive material and a second material.

3. The integrated circuit wiring structure in claim 2, wherein said first conductive material comprises polysilicon.

4. The integrated circuit wiring structure in claim 2, wherein said second material comprises one of a metal and a polymer.

5. The integrated circuit wiring structure in claim 2, wherein said second material acts as a placeholder for said gap.

6. The integrated circuit wiring structure in claim 1, wherein said gap holds ambient gases.

7. The integrated circuit wiring structure in claim 1, wherein said conductor comprises one of a gate conductor, a contact, and a wiring line.

8. An integrated circuit transistor structure comprising:
a gate conductor comprising a first conductive material and a second material;
non-deformable spacers adjacent said gate conductor; and
a gap between said gate conductor and said spacers.

9. The integrated circuit transistor structure in claim 8, wherein said first conductive material comprises polysilicon.

10. The integrated circuit transistor structure in claim 8, wherein said second material comprises one of a metal and a polymer.

11. The integrated circuit transistor structure in claim 8, wherein said second material acts as a placeholder for said gap.

12. The integrated circuit transistor structure in claim 8, wherein said gap holds ambient gases.

13. The integrated circuit transistor structure in claim 8, wherein said gap decreases resistance of said gate conductor.

14. An integrated circuit wiring structure comprising:
a conductor comprising polysilicon and a second material comprising one of a metal and a polymer;
non-deformable spacers adjacent said conductor; and
a gap between said conductor and said spacers.

15. The integrated circuit in claim 14, wherein said second material acts as a placeholder for said gap.

16. The integrated circuit in claim 14, wherein said gap holds ambient gases.

17. The integrated circuit in claim 14, wherein said gap decreases resistance of said conductor.

18. The integrated circuit in claim 14, wherein said conductor comprises one of a gate conductor, a contact, and a wiring line.

19. A method of forming a conductor in an integrated circuit structure, said method comprising:
forming a first conductive material;
depositing a second material over said first conductive material;
forming non-deformable spacers over said second material; and
annealing said integrated circuit structure to form a gap between said first conductive material and said non-deformable spacers.

20. The method in claim 19, wherein said annealing process drives said second material into said first conductive material.

21. The method in claim 19, wherein said forming of said first conductive material comprises depositing polysilicon.

22. The method in claim 19, wherein said depositing of said second material comprises depositing one of a metal and a polymer.

23. The method in claim 19, wherein said second material acts as a placeholder for said gap.

24. The method in claim 19, wherein said gap holds ambient gases.

25. The method in claim 19, wherein said gap decreases resistance of said conductor.

26. The method in claim 19, wherein said conductor comprises one of a gate conductor, a contact, and a wiring line.

27. A method of forming a transistor in an integrated circuit structure, said method comprising:
forming a gate conductor;
depositing a second material over said gate conductor;
forming non-deformable spacers over said second material; and
annealing said integrated circuit structure to form a gap between said gate conductor and said non-deformable spacers.

28. The method in claim 27, further comprising:
before said depositing of said second material, a process of undercutting sides of said gate conductor; and
after said depositing of said second material, a process of removing portions of said second material, such that said second material remains substantially only within undercut portions of said sides of said gate conductor.

29. The method in claim 28, wherein said undercutting and removing processes maintain a desired length of said gate conductor.

30. The method in claim 27, wherein said annealing process drives said second material into said gate conductor.

31. The method in claim 27, wherein said forming of gate conductor comprises forming polysilicon gates.

32. The method in claim 27, wherein said depositing of said second material comprises depositing one of a metal and a polymer.

33. The method in claim 27, wherein said second material acts as a placeholder for said gap.

34. The method in claim 27, wherein said gap holds ambient gases.

35. The method in claim 27, wherein said gap decreases resistance of said conductor.
